(19) United States
(12) Patent Application Publication
(10) Pub. No.: US 2004/0227200 A1
(43) Pub. Date: Nov. 18, 2004

(54) Micro-chemical chip, method of manufacturing the same, and method of molding optical unit

(75) Inventors: Satoshi Fukuyama, Numazu-Shi (JP); Hiroshi Murakoshi, Shizuoka-Ken (JP); Hajime Sudo, Chiba-Ken (JP); Hiroyuki Goto, Ebina-Shi (JP)

Correspondence Address: PILLSBURY WINTHROP, LLP, P.O. BOX 10500, MCLEAN, VA, 22102, US

(73) Assignees: TOSHIBA KIKAI KABUSHIKI KAISHA, Tokyo-To (JP); KABUSHIKI KAISHA TOSHIBA, Tokyo (JP); TOSHIBA CERAMICS CO., LTD., Tokyo-To (JP)

(21) Appl. No.: 10/438,320

(22) Filed: May 15, 2003

(51) Int. Cl. H01L 27/14; H01L 29/82; H01L 29/84

(52) U.S. Cl. 257/414

(57) ABSTRACT

A micro-chemical chip is comprised of a flow passage substrate (110) that includes a substrate (101) of transparent material having a plurality of flow passages (111) in one surface and an optical device (109) built in the other surface as a unit. In a micro-chemical chip manufacturing method according to the present invention, with metal dies 150 and 160 prepared to shape flow passages, wells, and an optical device(s), components such as the optical devices, flow passages, and the like are formed in a single molding process. The present invention is also directed to an optical unit manufacturing method where the atmospheric gas of nitrogen typically employed in the prior art is replaced with any gas of higher heat conductivity such as helium gas to heat and shape material in this alternative atmospheric gas and obtain the molded product.

### BACKGROUND OF THE INVENTION

The present invention relates to a micro-chemical chip and a method of manufacturing the same.

The present invention is also directed to a method of molding a glass optical unit, and more particularly, it relates to a molding procedure of the micro-chemical chip.

A typical example of a micro-chemical chip is a DNA chip that is a glass substrate of several tens millimeters long in each side where minute grooves of 100 μm in width and 50 μm in depth and/or recesses of several hundreds μm in diameter are created in swarms to serve as flow passages for spectrometric analysis.

Analysis with such a micro-chemical chip is dedicated to analyzation of chemicals flowing in the above-mentioned grooves or trapped in the recesses where after infrared or ultraviolet rays are directed to those minute grooves and/or recesses, reflected and/or transmitted light incident upon optical devices is guided to an analyzer unit.

Thus, the optical devices should essentially be highly precise for efficient propagation of the reflected and/or transmitted light with reduced loss, and above all, positional relations of the minute grooves and recesses to a variety of the optical devices must be finely adjusted for extreme accuracy.

FIG. 1 is a cross sectional view showing an exemplary structure of the micro-chemical chip while FIG. 2 is a plan view illustrating a configuration of a flow passage substrate suitable for the micro-chemical chip.

As can be seen in these figures, a flow passage substrate 10 and a lens substrate 20 adhered to its front side together make up a dual-layer structure where the former substrate includes a groove 2 and wells 3, 4 and 5 defined in one surface of a glass substrate 1 while the latter has a lens 12 seated on a cover glass 11. The cover glass 11 has openings 13 and 14 in positions registered with the wells 3 and 4 to inject fluid agent, and it also has an opening registered with the well 5 to take out chemical products.

The micro-chemical chip is usually used as follows:

Two fluid agents are injected in the wells 3 and 4, respectively, and then are released from the wells to flow passages so that the fluid agents reach at a merged point 6 of the flow passages to attain mixing and chemical reactions. The resultant reaction product is cumulatively reserved in the well 5. The product is optically analyzed in an analyzer unit encircled and denoted as 12 in the midst of an extension of the flow passages. For that purpose, built in the very position of the lens substrate is a lens 12 or an optical device through which incident beam 16 of ultraviolet light is directed, so that the transmitted light is spectrally analyzed to identify the reaction product.

Herein, a light source (not shown) is placed in front opposed to the lens 12 to emit ultraviolet or infrared light, and an analyzer 30 is located in the rear side of the glass substrate 1 to analyze transmitted light 17. The analyzer 30 is used for spectral analysis.

Now, referring to a flow chart of FIG. 3, a prior art micro-chemical chip manufacturing method will be described. Herein, the description will be supported by the exemplary micro-chemical chip as depicted in FIG. 1.

In this micro-chemical chip, the flow passage substrate 10 and the lens substrate 20 are separately fabricated.

First, in advance of creating the grooves, the glass substrate 1 has its surface coated with photo-resist (Step S1), and after the resist is exposed to irradiated rays of ultraviolet light with a mask of a predetermined pattern placed on top of the resist coated surface (Step S2), a treatment of development (Step S3) results in the resist being patterned. The resist patterned in this way is used in etching underlying glass with substance such as hydrogen fluoride HF to define the flow passages (grooves) (Step S4). Each step is necessarily followed by rinsing for purification, and especially after the etching, the rinsing is carried out cautiously (Step S5). The resist, which is after all needless, is peeled off (Step S6), and finally, the resultant substrate undergoes another process such as micromachining to make the wells 3, 4 and 5, respectively, as depicted in FIG. 1 (Step S7).

In this way, in the prior art, usually a semiconductor manufacturing process is employed to create the grooves in the micro-chemical chip.

The lens substrate is fabricated separate from the flow passage substrate.

First, the openings used for fluid agent injection are drilled in glass plate (the cover glass) for the lens substrate (Step S11). The work piece of fragile material requires a process somewhat special, but its fragility is not so much as to make the machining on it unexecutable.

Then, the lens is fabricated independently (Step S12). The lens may be machined in shape or molded. The processed lens is bonded to the cover glass 11 in a desired position by glue such as UV adhesive (Step S13).

For the purpose of optical analysis, light should be directed to the flow passages with accuracy, and hence, the optical device such as the lens or the like, when seated on the substrate, must be extremely carefully positioned. Since each flow passage is typically as wide as 100 μm, an accuracy of the fixation of the lens must be satisfactory to such an extent. In this way, the lens substrate is completed, having the optical device built therein.

Eventually, the lens substrate 20 and the flow passage substrate 10 are assembled with each other (Step S20), and thus, the desired micro-chemical chip is obtained.

Although, in the aforementioned example, the lens is provided in the cover glass, the lens may be attached to the reverse side, or namely, to the flow passage substrate so as to let the ultraviolet or infrared rays be incident on the flow passage substrate for spectrometric analysis.

Also, in order to alter a mixing rate of the two fluid agents, a cross section of each fluid flow passages (i.e., a depth of each groove) may be varied.

Such a prior art micro-chemical chip manufacturing method, however, has some disadvantages as stated below.

(1) When it is desired to have the grooves of more than one depths, the etching process to create the flow passages is not to be completed in one procedure for all the flow passages, and hence, the etching procedure should be iterated one or more times for each of several groups of different depths. When more than one types of fluid agents are to be used, the more the number of them is, the more often the etching must be carried out. As the etching is iterated more, considerably increased are the number of times of the iterated procedure of the resist coating, the number of masks and/or types of the masks, the frequencies of the repeated procedures of exposure to light, development, and rinsing. This is why the manufacturing process becomes more complicated and less cost-effective.

(2) Accurate alignment of the cover glass or the flow passage substrate with the optical device such as the lens is hard to accomplish in assembling them in unit. Thus, such precision assembling is hard to mechanize, and relying upon human labor and manual operation lead to a cost increase. As the adhesive used to fitting the optical device reduces its mass while being dried up, the accompanying shrinkage causes failure in alignment of the optical device.

(3) Since the etching step is inserted in the process of creating the flow passages, additional special external equipment and utilities are required.

(4) Exposure to the resist has to be performed with accuracy as high as the requirement for semiconductor devices, and therefore, an extravagant investment in facilities as required for semiconductor manufacturing processes is essential.

(5) Formation of the wells is carried out by means of micromachining separate from the formation of the flow passages, and this complicates the manufacturing process.

The conventional micro-chemical chip is an assembled unit by fitting separately prepared substrates together; namely, the flow passage substrate having the flow passages defined by means of a procedure such as the etching and the lens substrate having an optical unit or the lens seated in a transparent plate (refer to “Manufacturing of Quartz Electrophoretic Chip Using Micro-Machining Technology and Evaluation of Its Basic Characteristic” by Hiroaki Nakanishi et al, Technical Review of Shimadzu Corporation (Shimadzu Hyouron), Vol. 56, No. 1-2, August 1998).

According to this method, however, a variation of grooves required to be of different depths leads to an increase in the number of process stages beginning with the etching and the accompanying procedures, and the resultant complicatedness throughout the manufacturing process further leads to a cost increase. Moreover, there arise difficulties in precisely aligning the flow passage substrate with the optical unit, and also arises a problem of need of special expensive facilities for the exposure and etching procedures.

In order to overcome these disadvantages, a revised method has been proposed that the flow passages are defined in softened glass by metal die cast in fabricating an optical unit.

One proposed apparatus to implement this method consists of a quartz tube surrounded by a heater and a press mechanism provided in the tube where glass raw material is pressed between upper and lower molding dies. The quarts tube is initially evacuated to eliminate air and then filled with nitrogen gas so as to prevent oxidization of the metal dies.

Even with the revised method of molding, however, there still arises a problem.

(1) The metal dies reach an unsatisfactory level of temperature because of electric heating with insufficient calorie in the nitrogen atmosphere. Procrastination of the heating for the desired temperature leads to an elongated heating time and an increased consumption of power supply.

(2) Heating in an open state of the upper and lower dies results in the glass raw material getting not so high in temperature in its upper portion as in its lower portion; that is, there arises an uneven temperature distribution throughout the glass raw material to such an extent that fluidity of the glass material during the molding procedure is affected. Consequently, dimensioning accuracy to the molded product cannot be ensured. This problem becomes conspicuous especially with the nitrogen atmosphere due to its relatively poor thermal conductivity.

(3) Immediately after the metal dies are closed to proceed with the molding, the upper portion of the glass raw material experiences a rapid temperature increase. This causes a degradation of the accuracy in the molded product.

(4) When a glass bead is substituted for the glass raw material, an amount of conducted heat through the atmospheric gas greatly influences a promptness of the temperature increase, and a relatively small amount of the conducted heat due to the nitrogen atmosphere attains the undesirably poor heat efficiency.

(5) On the contrary, the molded product, which, while being cooled, emits a certain amount of calorie primarily conducted from the metal die touched with, releases more heat to the atmosphere as cooled in the open state of the metal dies. With the atmosphere of nitrogen gas, however, its poor heat conductivity accordingly degrades a heat radiating efficiency, which in turn requires procrastination of the cooling and then leads to an elongated cycle time.

(6) As depicted in FIG. 14, assuming that a grooved lower metal die 318 is used to emboss a plate-like material 330, the embossing molding in the nitrogen atmosphere is likely to have the gas remaining between the die and the material as shown in FIG. 15, which resultantly forms a bubbly pit termed “air pool 31” defectively in part of a molded product 30A.

### SUMMARY OF THE INVENTION

It is an object of the present invention to provide a cost-reduced and more efficient method of manufacturing an enhanced precision micro-chemical chip with an optical device built in.

Additionally, it is an object of the present invention to provide a manufacturing method of an optical unit of enhanced thermal efficiency and reduced defect in molding.

An exemplary micro-chemical chip according to the present invention includes a substrate of a transparent material having a plurality of flow passages in a first surface and an optical device built in a second or opposite surface as a unit, and a transparent cover plate adhered to the first surface.

An exemplary micro-chemical chip manufacturing method according to the present invention includes: prefabricating metal dies, one of the dies being provided with ridges suitable for shaping the plurality of the very finely sized flow passages while the other includes one or more recesses defined to mold the corresponding number of optical devices, positioning between the metal dies thermally softening transparent material and locating in the recesses optical elements prepared in advance, and press molding the transparent material in the atmosphere heated above a softening temperature for the transparent material whereby the plurality of the very fine flow passages are defined in a substrate, simultaneous with fitting one or more of the optical devices to the substrate as a unit.

An exemplary optical unit fabrication method according to the present invention includes: positioning glass material between a plurality of metal dies prepared in desired patterns, heating the metal dies and the glass material in the atmospheric gas of high thermal conductivity, and pressing the metal dies in contact in the atmospheric gas of high thermal conductivity, thereby shaping the glass material and molding an optical unit.

### BRIEF DESCRIPTION OF THE DRAWINGS

FIG. 1 is a cross sectional view showing a configuration of a prior art micro-chemical chip;

FIG. 2 is a plan view showing a planar surface structure of the micro-chemical chip of FIG. 1;

FIG. 3 is a flow chart illustrating stepwise manufacturing process of the prior art micro-chemical chip;

FIG. 4 is a cross sectional view showing a configuration of an exemplary micro-chemical chip according to the present invention;

FIG. 5 is a plan view showing the micro-chemical chip of FIG. 4;

FIG. 6 is a top plan view illustrating a lower one of dies used to mold a flow passage substrate for the micro-chemical chip of FIG. 4;

FIG. 7 is a sectional view taken along the line A-A of FIG. 6;

FIG. 8 is a bottom view illustrating the lower die used to mold the flow passage substrate for the micro-chemical chip of FIG. 4;

FIG. 9 is a sectional view taken along the line B-B of FIG. 8;

FIG. 10 is a flow chart illustrating an exemplary micro-chemical chip manufacturing method according to the present invention;

FIG. 11 depicts a step of placing material in position between the metal dies during the manufacturing procedure in FIG. 10;

FIG. 12 depicts a step of fitting pieces together during the manufacturing procedure in FIG. 10;

FIG. 13 illustrates a variation where a lens is simultaneously molded as well;

FIG. 14 is a diagram illustrating the press-molding of an optical unit;

FIG. 15 is depicts a defective molded product with air pool that has occurred in the prior art;

FIG. 16 is a sectional view showing a structure of a molding apparatus suitable for the optical unit manufacturing method according to the present invention;

FIG. 17 depicts routs of thermo conduction during the heating;

FIG. 18 depicts routs of thermo conduction during the cooling;

FIG. 19 is a graph showing thermal conductivity of the atmospheric gas;

FIG. 20 is a table providing permeability of quarts glass and diffusion length of various gases in the quarts glass; and

FIG. 21 depicts the molded product finished in the method according to the present invention.

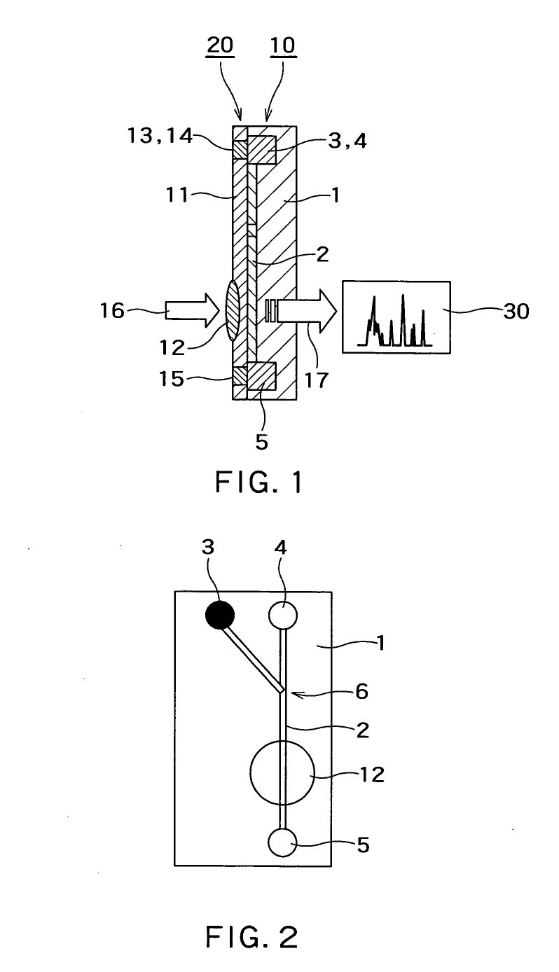

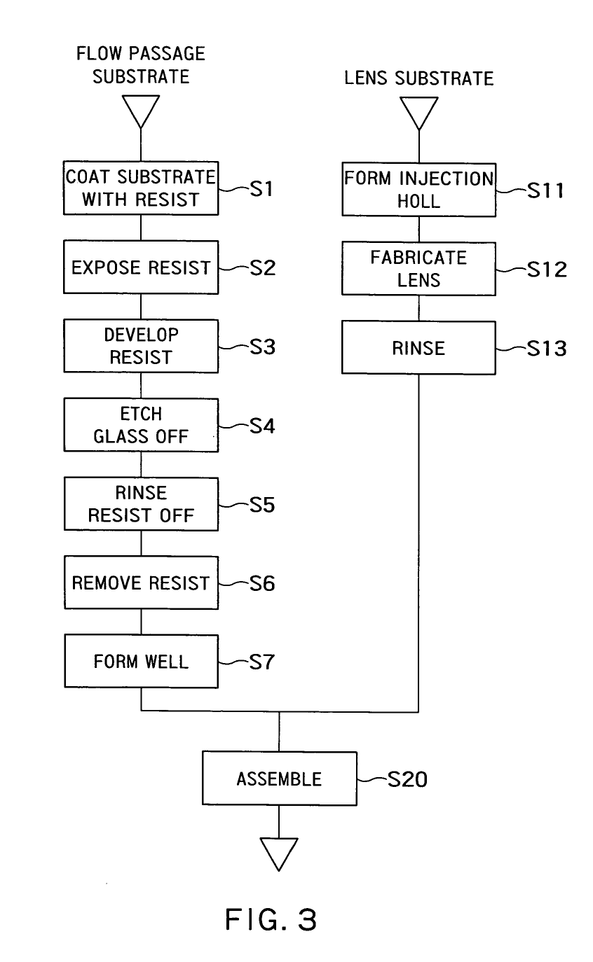

### DETAILED DESCRIPTION OF THE INVENTION

Referring to the accompanying drawings, preferred embodiments of the present invention will now be described in detail.

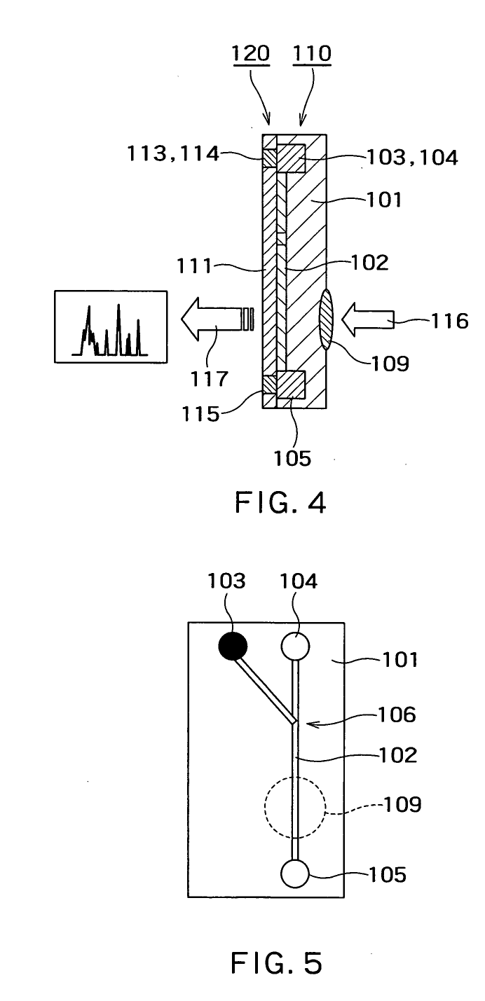

FIG. 4 is a sectional view illustrating an exemplary micro-chemical chip according to the present invention while FIG. 5 is a left side plan view of FIG. 4.

As can be recognized in the figures, a flow passage substrate 110 and a cover glass 120 are assembled with each other as a unit where the flow passage substrate 110 is made of a plate 101 of quartz or other transparent material having flow passages 102 and wells 103, 104 and 105 in its front surface and a lens 109 built in its reverse surface while the cover glass 120 includes openings 113 and 114 to inject fluid agent and an additional opening 115 to take products out, in positions registered with the wells 103 to 105, respectively. In this embodiment, the lens 9 is depicted as being spherical in shape, but instead, it may be aspherical in shape as in a cylindrical lens which is superior in converging/focusing light along the flow passages to propagate converged/focused beam to an analyzer.

This embodiment is characteristic in that the lens 109 is built in position simultaneous with formation of the flow passages and wells. This will be further detailed below.

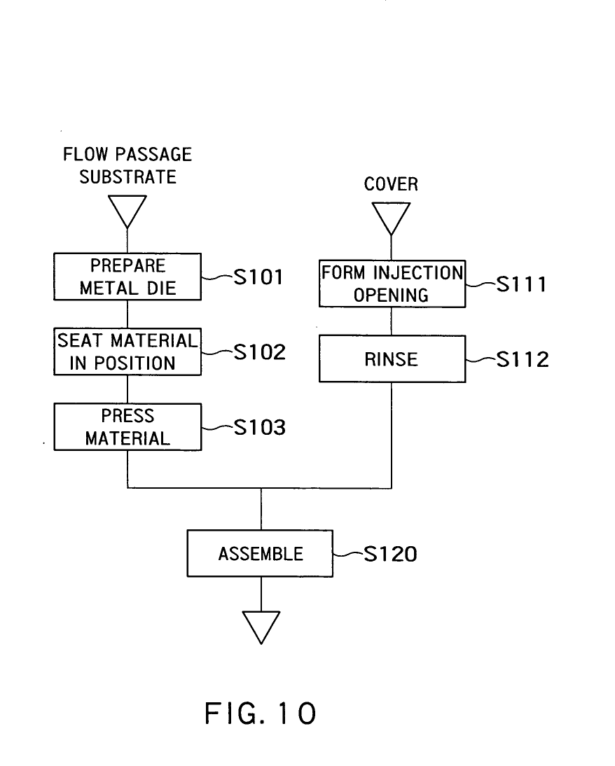

FIG. 10 is a flow chart illustrating a micro-chemical chip manufacturing method according to the present invention.

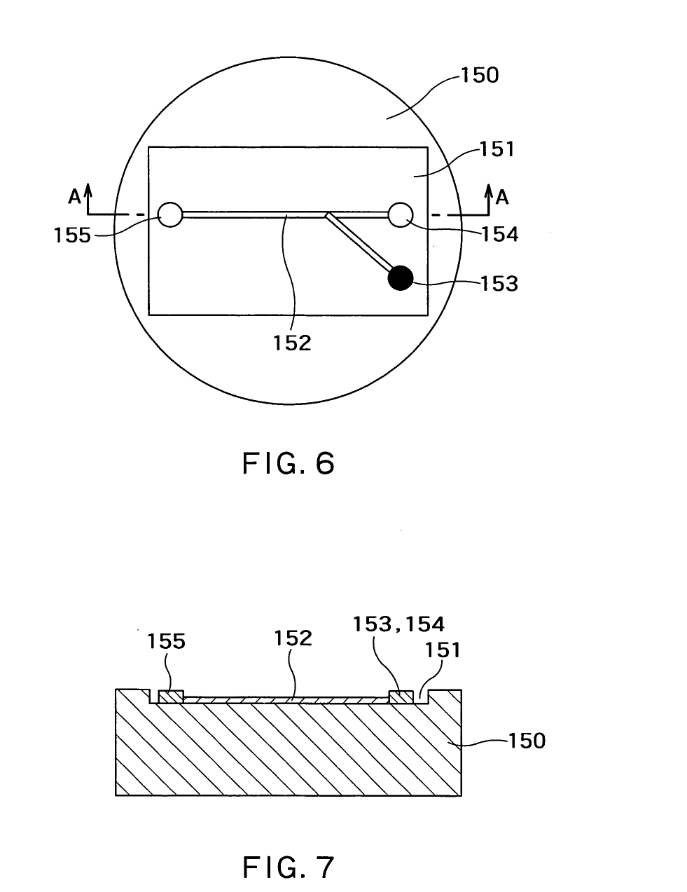

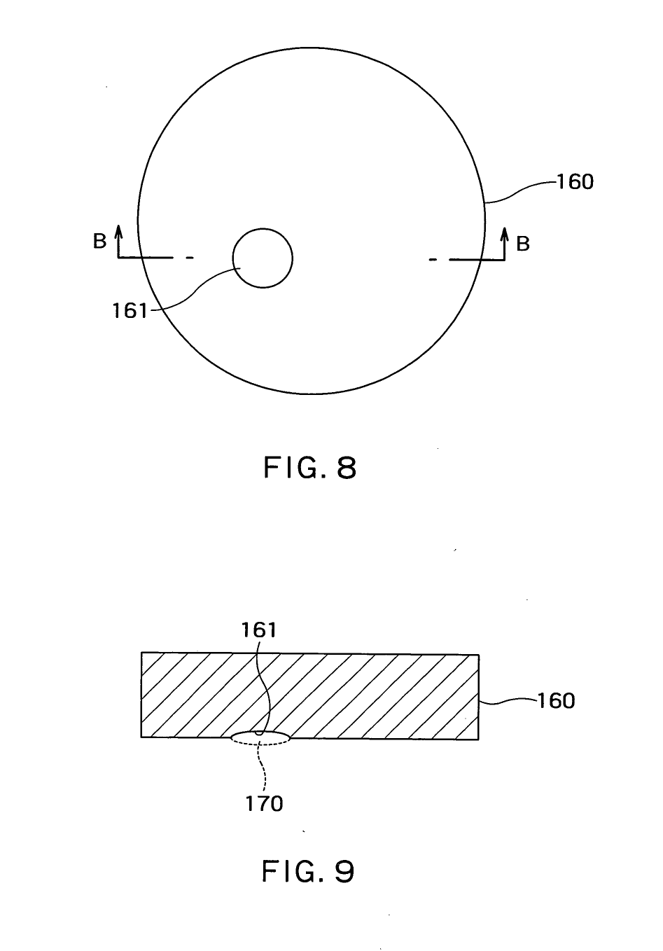

First, metal dies are prefabricated (Step S101). FIG. 6 is a top plan view of a lower one of the metal dies, FIG. 7 is a cross sectional view along the line A-A of the same, FIG. 8 is a bottom plan view of an upper one of the metal dies, and FIG. 9 is a cross sectional view along the line B-B of the same.

The lower die 150 has a recess 151 which is dimensioned to match the flow passage substrate and which includes a ridge 152 and projections 153 to 155 to shape a flow passage and wells, respectively.

The upper die 160 has a concavity 161 contoured in conformity with a lens. FIG. 9 depicts a lens 170 that is seated in the recess 161 while the flow passage substrate is fabricated with the dies.

These raised and depressed portions are typically machined in shapes. Each component set of the molding and the molded is symmetrical in both shape and position as in mirror projection, namely, the raised portions in the dies to the grooves and wells in the flow passage substrate. Also, in this embodiment, it is assumed that all the flow passages are the same in depth, and if it is desired to vary a grooved depth from one passage to another, there is no difficulty in prefabricating the metal dies. With the metal dies fabricated as finely as possible, precision of the produced flow passage substrate can be easily enhanced as much.

Also, in this embodiment, the lower die serves to shape the flow passages and wells, and such molding patterns may be exchanged between the upper and lower dies.

Moreover, although the molding pattern for the flow passages is machined in this embodiment, the dies may be prepared by etching or any other appropriate way if more miniaturized pattern is desired. In such a case, however, additional process to and/or separate process from shaping the flow passages with the raised portions in the die are needed to have the grooves and wells of varied depths.

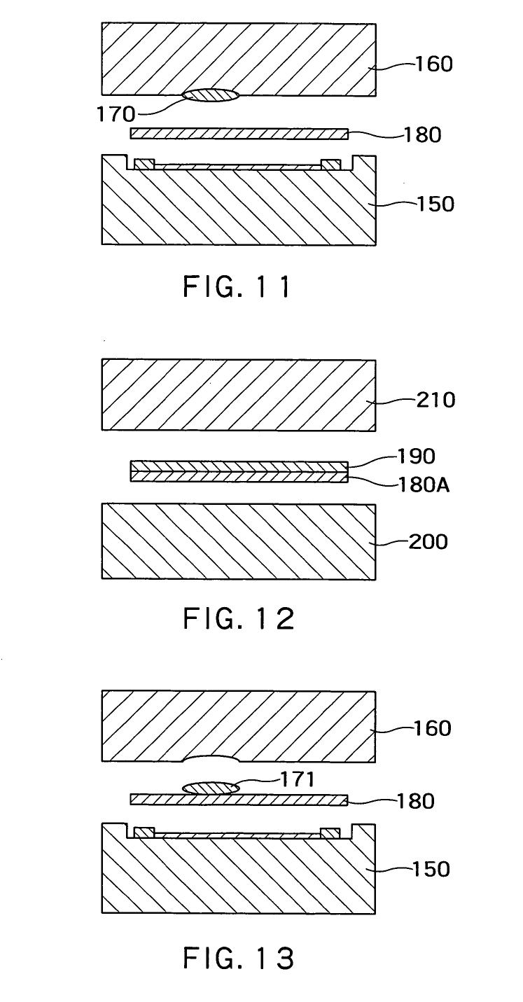

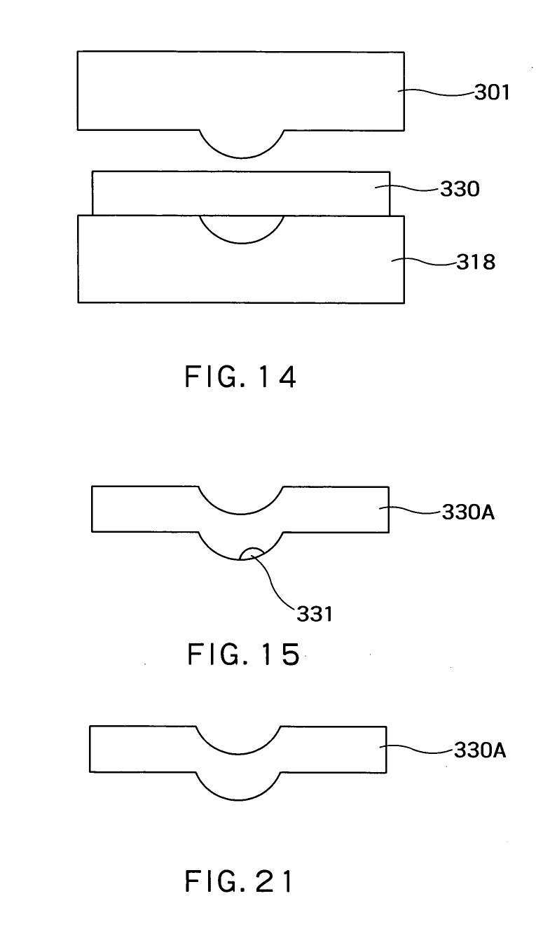

Then, as shown in FIG. 11, positioned between metal dies 150 and 160 is a work piece 180 of which the flow passage substrate is to be made (Step S103). In this case, synthetic quarts glass containing 2000 ppm of OH radicals is used.

The concavity 161 defined in the upper die 160 holds the lens 170 that is separately prefabricated and fitted therein by glue of considerably low adhesiveness.

In order to adjust contact between the metal dies to ensure appropriate positioning of the lens and grooves, pins (not shown) are used to attain precise alignment for both the upper and lower metal dies. As a consequence, in this embodiment, an amount of maladjustment between the upper and lower metal dies is as small as several micrometers. Allowing for a width of grooves as long as 100 μm, this amount proves a sufficient precision.

The pressing is performed next (Step S103). At this step, the upper and lower metal dies joined together are heated up to 1450° C. along with the quarts glass therebetween to soften the same, thereby attaining high precision pressing. The pressing force is 800 kgf. Also, to enhance pattern transferability, the molding procedure is carried out in a vacuum condition.

In this way, a groove is defined in the softened quarts glass plate just as being thrust by the ridge in the lower die. The lens is fitted to the quartz glass plate as a unit with a very high precision of registration between them.

After that, the flow passage substrate thus prepared is assembled with the cover glass. As illustrated in the flow chart of FIG. 10, a quarts glass plate serving as the cover glass is drilled to make openings through which fluid is to be injected and products are taken out (Step S111), and then the glass plate is rinsed (Step S112). As will be recognized from the flow chart, since the lens is adequately positioned in and fitted to the flow passage substrate, no process to the cover glass is necessary as with the lens.

Then, the flow passage substrate 180A, which has already been pressed with the lens seated therein, is overlaid with the cover glass 190 as shown in FIG. 12. These joined elements are pressed together in the atmosphere heated to a high temperature, and then, the assembling is completed (Step S120).

Positioning the cover glass 190 relative to the flow passage substrate 180′ is so simple an operation as just registering apertures defined in the cover glass with relatively large wells formed in the flow passage substrate.

This assembling procedure may be performed by using a dedicated laminating/pressing machine, or otherwise, the molding apparatus used for molding the flow passage substrate may be an alternative.

The micro-chemical chip obtained in the aforementioned manner does not have to undergo additional grooving process, and furthermore, the precision in registering with the optical device such as a lens can be greatly improved.

Although, in the aforementioned embodiment, a lens element is shaped along with the planar substrate, a lens material 171 of quarts glass may be seated on the work piece 180 of the quarts glass plate. The material of the lens element is not limited to the quarts glass but may be any of alternatives of suitable optical characteristics. For instance, any of substances including polydimethylsiloxane, polyethylenetelephthalate, polymetylmethacrylate, polycarbonate, soda-lime glass, borosilicate glass, and silica glass may be substituted.

In the aforementioned embodiment, the lens is fabricated in ordinary shape, but if desired, it may be shaped in any other appropriate form like a cylindrical lens.

As has been described, in the micro-chemical chip manufacturing method according to the present invention, a flow passage substrate is made of a substrate of transparent material which has a plurality of flow passages in one surface and an optical element built in the other surface as a unit, and therefore, high precision of alignment of the flow passages with the optical element can be attained.

Also, in accordance with the present invention, metal dies prepared for shaping the flow passages and wells enable to mold the optical element for analyzation along with the flow passages and wells in a single procedure. Hence, high precision alignment of the flow passages with the optical element can be obtained, and additionally, the manufacturing process can be simplified while cost for the components is reduced.

Moreover, since exposure and etching procedures are omitted, facilities for them are needless, and avoiding use of dangerous gas eliminates needs of equipment and/or facility for waste gas treatment.

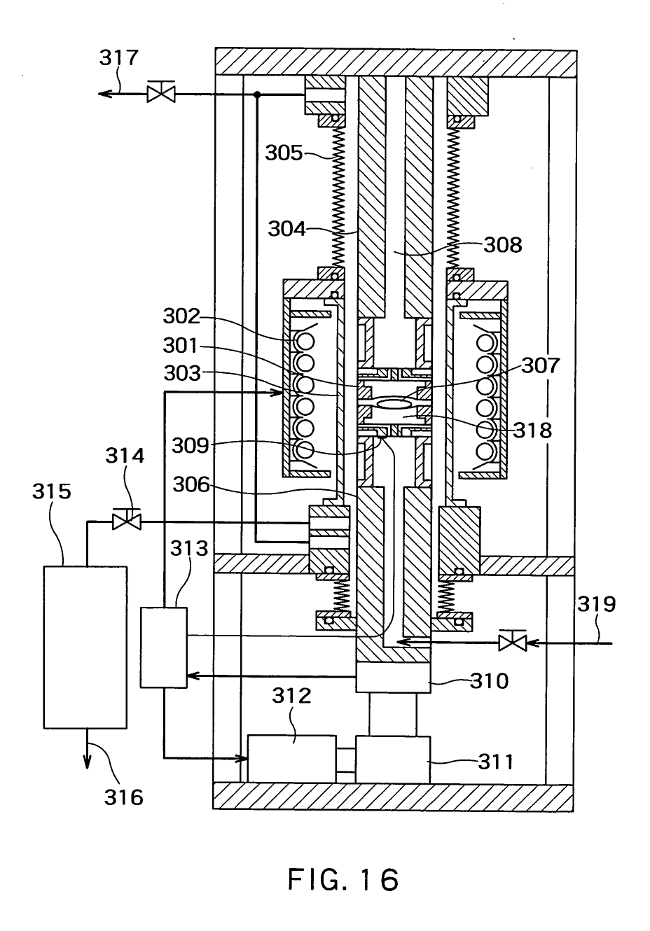

FIG. 16 is a schematic diagram showing the molding apparatus applied in any of the aforementioned embodiments.

A glass material 307, after seated between upper and lower metal dies 301 and 318, is then molded. The upper metal die 301 is fixed to an upper shaft 304 secured to a frame. On the other hand, the lower metal mold 318 is mounted on a vertically reciprocating lower shaft 306. The lower shaft 306 has its lower portion coupled with a jack 311 that is actuated by a motor 312 to develop pressing force. A sensor 310 is also provided in the vicinity of the lower shaft 306 so as to detect the pressing force.

The pressing force detected by the sensor 310 is differentiated from a predetermined value transmitted to the output regulator 313 in advance, thereby adjusting motor power.

The metal dies are enclosed by the quarts tube 303 that is surrounded by a group of lamps 302 emitting infrared light. The lower die 318 is connected to a thermocouple 309 to determine its temperature.

The quarts tube 303 in combination with the infrared light lamps 302 provide the optimum efficiency in heating the dies and molded material, and hence, a flexible member 305 coupling them to the frame allows them to vertically reciprocate depending upon dimensions and types of the metal dies.

The output regulator 313 serves to adjust an instruction signal output to the infrared light lamps 302, depending upon a difference of the determined temperature at the thermocouple 309 from the predetermined temperature level.

In order to permit the quarts tube 303 to create vacuum condition within itself, a vacuum pump 15 is coupled thereto. Evacuation is controlled by opening and closing a valve designated by reference number 314, and evacuated air is pumped out through a drain 316.

Furthermore, the upper and lower shafts 304 and 310 are hollow to let air 308 pass therethrough and cool the metal dies and the molded material, and a flow rate of heating or cooling air is controlled by a valve 319.

An operation of the apparatus will now be described. Herein, it is assumed that the molded material is a glass bead (ball-shaped glass).

First, keeping the valve 314 open, a molding chamber (i.e., the quarts tube 303) is evacuated into vacuum by a pump 315 to pump out oxygen from the molding chamber 303. This step is necessary to eliminate all the remaining oxygen in the molding room which otherwise gives adverse effects such as oxidation of the metal dies during heating, which may cause degradation of quality of the molded product.

After evacuating the chamber to a predetermined pressure level, highly purified helium gas 308 is supplied through the valve 319 in FIG. 16. As the atmosphere of helium gas is brought about in the molding chamber 303, the output regulator 313 permits the infrared light lamps 302 to turn on to heat the metal dies and the glass material 323 up to a predetermined temperature level.

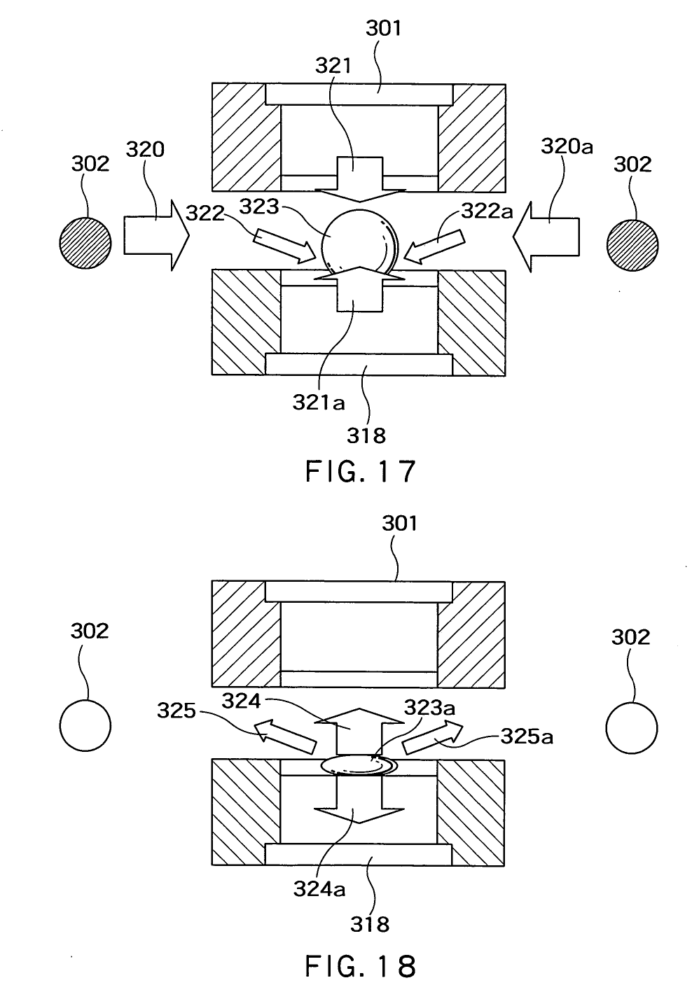

FIG. 17 is a diagram showing a model of thermal conduction during the heating.

As recognized in the figure, during the heating, there are predicted three routs of heat conduction, namely, direct propagation from the infrared light lamps denoted as 320 and 320a, propagation from the metal dies as 321 and 321a, and propagation from the glass material and its periphery as 322 and 322a. In the condition before pressing as depicted in FIG. 17, only heat conducted from the lower one 318 of the metal dies is observed.

Although the heating procedure is possibly performed in a vacuum condition, heat conducted from the glass material and its periphery is unexpectable. Especially, when a glass bead is to be processed as shown in FIG. 17, heat is hardly propagated from the lower metal die 318 through an interface with the glass bead 323, and thus, heating efficiency is not so much.

Thus, unlike the prior art where the heating is carried out in the atmospheric gas of nitrogen, the present invention employs the atmospheric gas of helium during the heating.

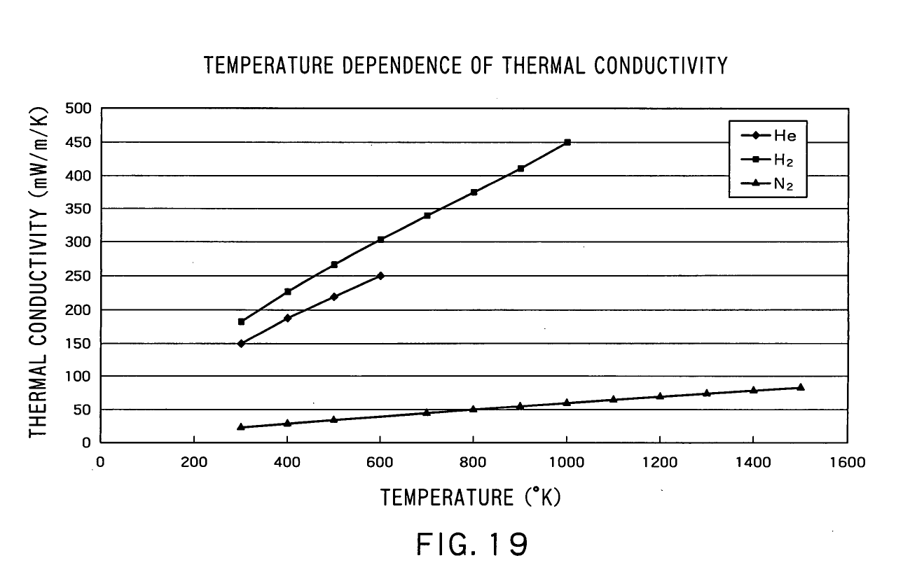

FIG. 19 depicts temperature dependence of thermal conductivity with both helium and hydrogen. From the graphs, it is recognizable that the helium gas is about 4 times greater in thermal conductivity than the nitrogen gas. As to neon gas, the graphs show nothing herein, but it is well known that it shows superior heat conductivity, compared with the nitrogen gas.

Thus, the helium gas contributes as thermal propagation medium to a considerably high calorie of conducted heat to the glass material 323 during the molding, and this resultantly enhances thermal efficiency, which leads to a more prompt increase in temperature at the metal dies and the glass material. Also, this is useful to avoid uneven temperature distribution throughout the glass material.

When the metal dies reaches a predetermined level of temperature, the lower die fixed to the lower shaft is raised to shape the glass material. In this way, the die pattern is cast to the glass material to attain the desirably molded product.

After completing the molding, the nitrogen gas is used to cool the molded product till it reaches a sufficiently reduced temperature to take it out.

FIG. 18 is a diagram showing thermal conduction during the cooling. The molded glass material 323a raiates heat that propagates through the metal dies, as denoted in the heat conducting routes 324 and 324a, and the glass material itself also release heat propagating in the routs denoted as 322 and 322a. In such a case, the atmosphere of the helium gas of superior heat conductivity quickens cooling.

With these assumptions being satisfied, a simulation of molding was brought into practice. First, a thermocouple was applied to the glass material itself in addition to that secured to the lower metal die to determine temperature. Without shaping the glass material, simply temperature was determined at the metal die and the glass material, respectively.

As a consequence, observed was that the helium gas is considerably more useful to reduce the above-mentioned temperature difference during any procedure of heating, warming, and cooling in comparison with the nitrogen gas. With the helium gas, time and supplied electric power required for heating were also reduced as low as 80% for the operation with the nitrogen gas while those required for cooling were reduced as low as 60%.

Collateral with the aforementioned, use of the helium gas was effective in that quarts material molded in the helium atmosphere yields less undesired casting like occurrence of the above-mentioned air pool. Experimentally observed was the defective molding in the atmospheric gas of nitrogen that caused the air pool, but it was proved that the identical experiment in the atmospheric gas of helium eliminated the detect of occurrence of the air pool.

This is because the helium gas is of elements that more easily dissolve in the quarts glass, compared with the nitrogen gas.

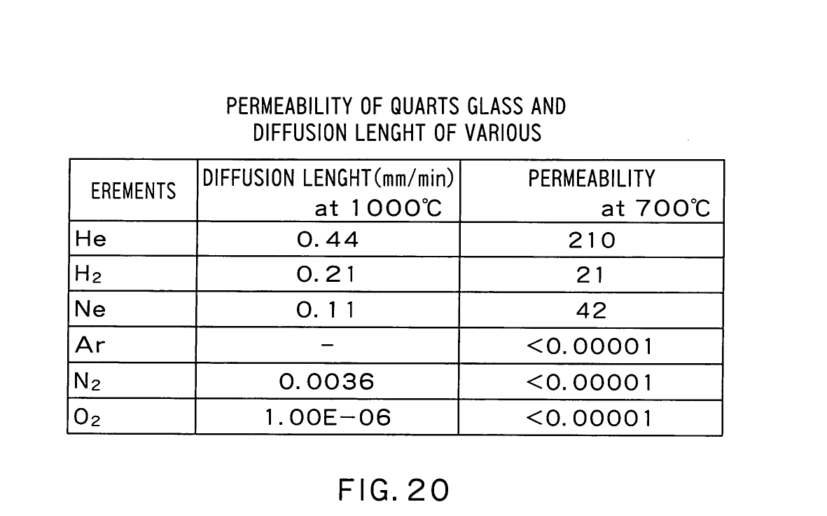

FIG. 20 is a table giving a solubility and diffusion length of various gasses to quarts glass. This table provides data on the diffusion length of those gasses into the quarts glass in a temperature range of 1000° C. and their respective permeabilities in the range of 700° C. Herein, the diffusion length is a distance at which the various gasses diffuse into the quarts glass in a unit time while the permeability is a degree of the permeating gasses into the quarts glass, especially, a volume of the gasses permeating through an area of 1 square centimeters in a unit time under differential pressure of 1 cmHg in the temperature range of 700 □. Allowing for a thickness of the tested material, however, these data are all represented in values of the volumes divided by the thickness.

In FIG. 20, it is noticeable that permeability of the quarts glass with helium is conspicuous and diffusion coefficient through the quarts glass is the greatest with the same. Especially, a ratio of the permeating helium is strikingly greater in comparison with other gases, and particularly, compared with the nitrogen gas that has been used in the prior art.

Thus, it is proved that a choice of the atmospheric gas of helium, neon or the like during the molding brings about a reduction in occurrence of the defective air pool because gasses of such elements, once confined in a space between the quarts glass and the metal dies, are more absorbable, and that the helium gas is the optimum when used for the atmospheric gas during the molding.

As has been described, in accordance with the present invention, after a glass raw material is seated in position between metal dies, press molding is carried out while both the metal dies and the glass material are heated in the atmospheric gas of higher thermal conductivity than nitrogen gas, so as to obtain an optical unit, thereby enhancing efficiency of heat conduction, shortening required times for heating and cooling, and improving manufacturing efficacy.

In addition to that, power consumption required for the heating is reduced, and all the factors together enable an attainment of cost reduction.

It is noteworthy that especially use of helium gas or neon gas for the atmospheric gas is useful to avoid unsatisfactory casting accompanied by air pool.

What is claimed is:

1. A micro-chemical chip comprising
a flow passage substrate that includes a substrate of transparent material having a plurality of flow passages in a first surface and an optical element in the opposite or second surface as a unit, and
a transparent cover plate assembled with the first surface.

2. The micro-chemical chip according to claim 1, wherein the optical element is an optical lens.

3. The micro-chemical chip according to claim 1, wherein the substrate of transparent material is made of any of substances including polydimethylsiloxane, polyethylenetelephthalate, polymetylmethacrylate, polycarbonate, soda-lime glass, borosilicate glass, and silica glass.

4. A method of manufacturing a micro-chemical chip comprising:
prefabricating metal dies, one of the dies being provided with ridges suitable for shaping a plurality of very finely sized flow passages while the other includes one or more recesses defined to mold the corresponding number of optical devices,
positioning between the metal dies thermally softening transparent material and locating in the recesses optical elements prepared in advance, and
press molding the transparent material in the atmosphere heated above a softening temperature of the transparent material,
whereby the plurality of the very fine flow passages are defined in a substrate, simultaneous with fitting one or more of the optical devices to the substrate as a unit.

5. The method according to claim 4, wherein each of the optical elements has a mass equivalent to a volume of each of the recesses, and is prefabricated in a shape in accord with a contour of the recess to serve as an optical lens.

6. The method according to claim 4, wherein each of the optical elements is an entity of optical glass having a mass equivalent to a volume of each of the recesses.

7. The method according to claim 4, wherein the transparent material is any of substances including polydimethylsiloxane, polyethylenetelephthalate, polymetylmethacrylate, polycarbonate, soda-lime glass, borosilicate glass, and silica glass.

8. A method of manufacturing an optical unit comprising: positioning glass material between metal dies shaped in desired patterns,
heating the metal dies and the glass material in the atmospheric gas of higher thermal conductivity compared with nitrogen gas, and
pressing the metal dies in contact, thereby shaping the glass material to mold an optical unit.

9. The method according to claim 8, wherein the atmospheric gas higher in thermal conductivity than nitrogen gas is helium gas.

10. The method according to claim 8, wherein the atmospheric gas higher in thermal conductivity than nitrogen gas is neon gas.

11. The method according to claim 8, wherein the glass material is quarts glass.

12. The method according to claim 8, wherein the optical unit is a micro-chemical chip.
